(19) United States
(12) Patent Application Publication
(10) Pub. No.: US 2008/0128875 A1
(43) Pub. Date: Jun. 5, 2008

(54) INTEGRATED CIRCUIT WITH ON-CHIP MEMORY AND METHOD FOR FABRICATING THE SAME

(75) Inventor: Kenichi KIMURA, Kanagawa (JP)

Correspondence Address: NIXON PEABODY, LLP, 401 9TH STREET, NW, SUITE 900, WASHINGTON, DC, 20004-2128, US

(73) Assignee: OKI ELECTRIC INDUSTRY CO., LTD., Tokyo (JP)

(21) Appl. No.: 12/017,468

(22) Filed: Jan. 22, 2008

Related U.S. Application Data
(62) Division of application No. 10/893,926, filed on Jul. 20, 2004.

(51) Int. Cl. H01L 21/768; H01L 23/52

(52) U.S. Cl. 257/665; 438/599; 257/E23.141; 257/E21.575

(57) ABSTRACT

An integrated circuit includes an on-chip memory having bit lines, which is formed in a metal layer; and an embedded passage wiring that is arranged in the metal layer or above so as to avoid a cross-talk noise with the bit lines. The embedded passage wiring is electrically connected to predetermined terminals to route a signal line over the on-chip memory.

### TECHNICAL FIELD OF THE INVENTION

The present invention relates to an integrated circuit with an on-chip memory (embedded memory on LSI chip), and more particular to, a logic signal routing over on-chip memories, such as RAM and ROM, in an LSI chip.

### BACKGROUND OF THE INVENTION

When logic signals are routed over on-chip memories, crosstalk noise should be reduced for reliable operation. For example, when signal lines are routed over on-chip memories to extend parallel to bit lines of the memories, crosstalk noise occurs.

Conventionally, signal lines, arranged over on-chip memories, are routed by a round-about way to reduce crosstalk noise with bit lines. Alternately, an LSI is designed to have a more integration so that signal lines are formed several layers over on-chip memories.

However, if signal lines are routed by a round-about way to on-chip memories, the LSI chip would become larger in size. If an LSI is designed to have a more integration, fabrication costs of the LSI would increase. If signal lines are routed by a round-about way to on-chip memories or an LSI is designed to have a more integration, fabrication costs of the LSI would increase.

### OBJECTS OF THE INVENTION

An object of the present invention to provide an integrated circuit, which may reduce crosstalk noise without remarkable increasing of fabrication cost and chip size.

Additional objects, advantages and novel features of the present invention will be set forth in part in the description that follows, and in part will become apparent to those skilled in the art upon examination of the following or may be learned by practice of the invention. The objects and advantages of the invention may be realized and attained by means of the instrumentalities and combinations particularly pointed out in the appended claims.

### SUMMARY OF THE INVENTION

According to an aspect of the present invention, an integrated circuit includes an on-chip memory (embedded memory on LSI chip) having bit lines, which is formed on a metal layer; and an embedded passage wiring (reserve pass line) that is arranged on the metal layer or above so as to avoid a cross-talk noise with the bit lines. The embedded passage wiring is electrically connected to a signal line to route the signal line over the on-chip memory.

According to another aspect of the present invention, a method for fabricating an integrated circuit including the following steps:

providing an on-chip memory with bit lines on a semiconductor substrate;

forming an embedded passage wiring at an appropriate region so as to avoid a cross-talk noise with the bit lines; and

electrically connecting the embedded passage wiring to a signal line to route the signal line over the on-chip memory.

The embedded passage wiring may be arranged to have a sufficient distance from the bit lines.

The embedded passage wiring may include a first line extending perpendicular to the bit lines, and a second line extending parallel to the bit lines. The embedded passage wiring may include a first line extending perpendicular to the bit lines, and a second line extending in a direction slightly leaning from the bit lines. The embedded passage wiring may include a first line extending perpendicular to the bit lines, and second lines extending parallel to the bit lines but cutting across each other at a predetermined point at least in a plane view.

The integrated circuit comprises a plurality of the on-chip memories, which are located adjacent each other not to have any specific region therebetween for a signal line.

### BRIEF DESCRIPTION OF THE DRAWINGS

FIG. 1 is an integrated circuit according to a first preferred embodiment of the present invention.

FIG. 2 is an illustration showing a modified version of first to third preferred embodiment of the present invention.

FIG. 3 is an integrated circuit according to a second preferred embodiment of the present invention.

FIG. 4 is an integrated circuit according to a third preferred embodiment of the present invention.

### DETAILED DISCLOSURE OF THE INVENTION

In the following detailed description of the preferred embodiments, reference is made to the accompanying drawings which form a part hereof, and in which is shown by way of illustration specific preferred embodiments in which the inventions may be practiced. These preferred embodiments are described in sufficient detail to enable those skilled in the art to practice the invention, and it is to be understood that other preferred embodiments may be utilized and that logical, mechanical and electrical changes may be made without departing from the spirit and scope of the present inventions. The following detailed description is, therefore, not to be taken in a limiting sense, and scope of the present inventions is defined only by the appended claims.

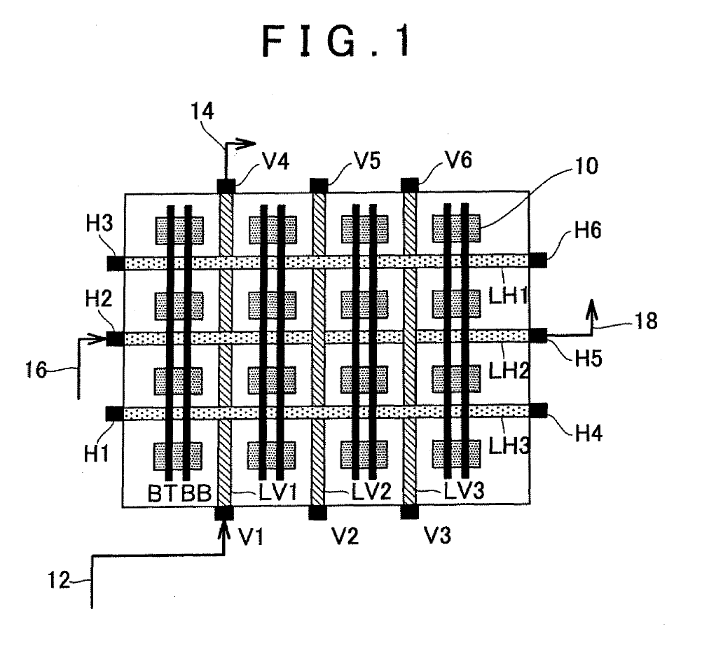

FIG. 1 is an integrated circuit according to a first preferred embodiment of the present invention. An integrated circuit includes an on-chip memory (embedded memory on LSI chip) having memory cells 10, which are arranged in matrix, and bit lines BT and BB, which are formed on a metal layer. The integrated circuit also includes embedded passage wiring (reserve pass line) LV1-LV3 and LH1-LH3, which extend perpendicular and parallel to the bit lines, respectively. The embedded passage wiring LV1-LV3 and LH1-LH3 may be formed on the same layer of the bit lines or upper. The embedded passage wiring LV1-LV3 and LH1-LH3 are metal preparation lines to be used for signal line routing. The signal lines may be system clock line, data bus, etc. The embedded passage wiring LV1-LV3 and LH1-LH3 are formed in advance before routing process of signal lines.

Terminals V1 and V4 are connected to the ends of the embedded passage wiring LV1; terminals V2 and V5 are connected to the ends of the embedded passage wiring LV2; and terminals V3 and V6 are connected to the ends of the embedded passage wiring LV3. Terminals H1 and H4 are connected to the ends of the embedded passage wiring LH3; terminals H2 and H5 are connected to the ends of the embedded passage wiring LH2; and terminals H3 and H6 are connected to the ends of the embedded passage wiring LH1.

The embedded passage wiring LV1-LV3 and LH1-LH3 are electrically connected to signal lines via the terminals to route the signal lines over the on-chip memory using a Place & Routing tool. In FIG. 1, signal lines 12 and 14 are connected to the embedded passage wiring LV1 via the terminals V1 and V4, respectively. Signal lines 16 and 18 are connected to the embedded passage wiring LH2 via the terminals H2 and H15, respectively. The embedded passage wiring LV1-LV3 and LH1-LH3 are arranged to have a sufficient distance from the bit lines to avoid crosstalk noise.

The invention is applicable to other types of circuit having lines that are easily affected by noise.

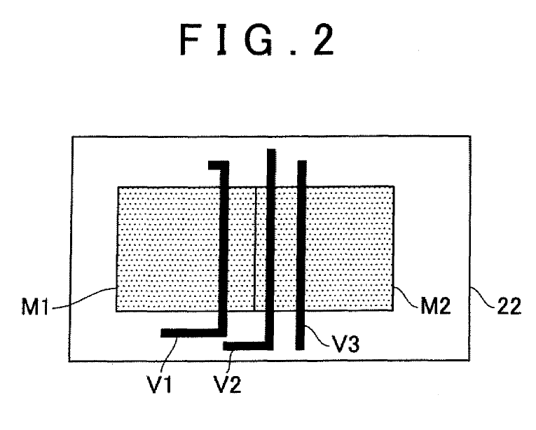

FIG. 2 is an illustration showing a modified version of first to third preferred embodiment of the present invention. An integrated 22 circuit may include a plurality of on-chip memories M1 and M2, which are located to be in contact with each other. The on-chip memories M1 and M2 may be located adjacent each other not to have any specific region for a signal line. In FIG. 2, V1-V3 represent signal lines. According to this structure, shown in FIG. 2, signal lines V1-V3 can be routed over the on-chip memories M1 and M2 without providing a special region for routing signal lines. The modification shown in FIG. 2 is applicable not only to the first preferred embodiment, but also to the following second and third preferred embodiments as well.

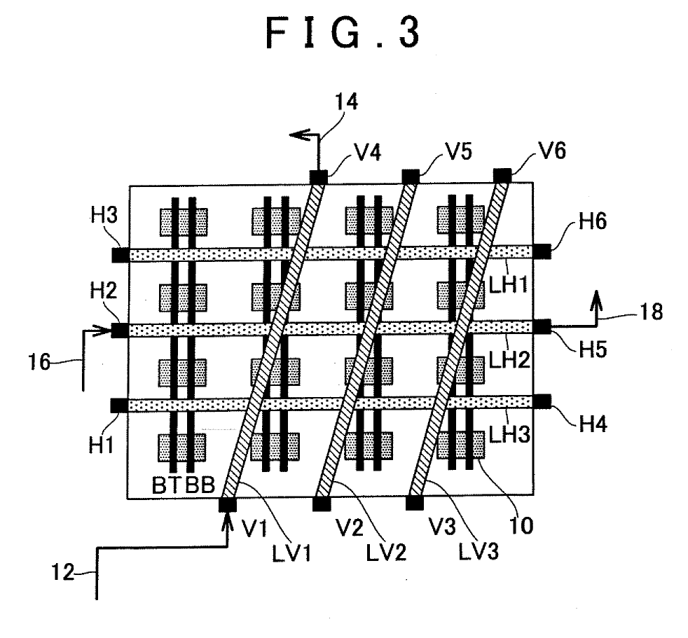

FIG. 3 is an integrated circuit according to a second preferred embodiment of the present invention. An integrated circuit includes an on-chip memory having memory cells 10, arranged in matrix, and bit lines BT and BB, which are formed on a metal layer. The integrated circuit also includes embedded passage wiring (reserve pass line) LV1-LV3 and LH1-LH3. The embedded passage wiring LV1-LV3 are arranged to extend in a direction, which is slightly leaning from the bit lines. The embedded passage wiring LH1-LH3 are arranged to extend perpendicular to the bit lines BT and BB. The embedded passage wiring LV1-LV3 and LH1-LH3 are cutting each other at least in a plane view.

The embedded passage wiring LV1-LV3 and LH1-LH3 are formed on the same layer as the bit lines or upper. The embedded passage wiring LV1-LV3 and LH1-LH3 are metal preparation lines to be used for signal line routing.

Terminals V1 and V4 are connected to the ends of the embedded passage wiring LV1; terminals V2 and V5 are connected to the ends of the embedded passage wiring LV2; and terminals V3 and V6 are connected to the ends of the embedded passage wiring LV3. Terminals H1 and H4 are connected to the ends of the embedded passage wiring LH3; terminals H2 and H5 are connected to the ends of the embedded passage wiring LH2; and terminals H3 and H6 are connected to the ends of the embedded passage wiring LH1.

The embedded passage wiring LV1-LV3 and LH1-LH3 are electrically connected to signal lines (12, 14, 16 and 18) via the terminals to route the signal lines over the on-chip memory using a Place & Routing tool. In FIG. 3, signal lines 12 and 14 are connected to the embedded passage wiring LV1 via the terminals V1 and V4, respectively. Signal lines 16 and 18 are connected to the embedded passage wiring H2 via the terminals H2 and H5, respectively.

According to the second preferred embodiment, the embedded passage wiring LV1-LV3 are arranged to extend not parallel to the bit lines BT and BB but in a direction slightly leaning from the bit lines. As a result, the signal lines formed with the embedded passage wiring LV1-LV3 are not affected by crosstalk noise.

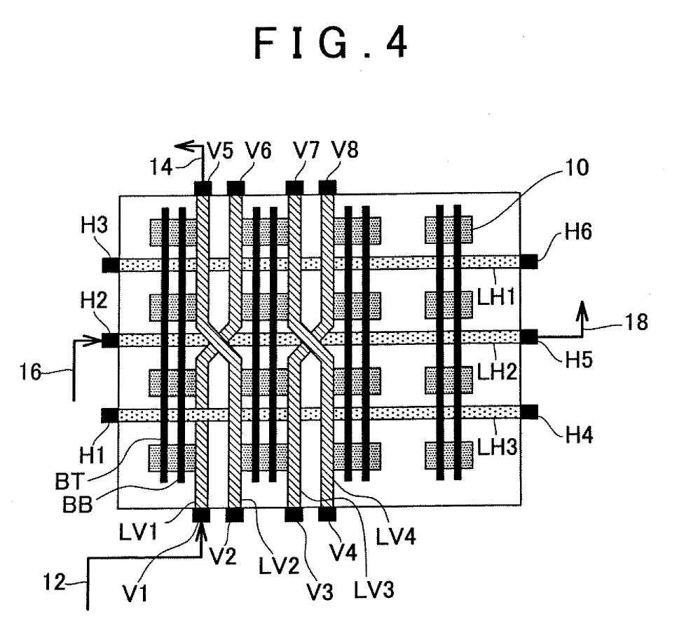

FIG. 4 is an integrated circuit according to a third preferred embodiment of the present invention. An integrated circuit includes an on-chip memory having memory cells 10, arranged in matrix, and bit lines BT and BB, which are formed on a metal layer. The integrated circuit also includes embedded passage wiring (reserve pass line) LV1-LV4 and LH1-LH3. The embedded passage wiring LV1-LV4 are arranged to extend fundamentally parallel to the bit lines BT and BB. The embedded passage wiring LV1 and LV2 are arranged to cut across each other at a predetermined point at least in a plane view so as to decrease the length of signal lines that continuously extends parallel to the bit lines. In the same manner, the embedded passage wiring LV3 and LV4 are arranged to cut across each other at a predetermined point at least in a plane view so as to decrease the length of signal lines that continuously extends parallel to the bit lines. The embedded passage wiring LH1-LH3 are arranged to extend perpendicular to the bit lines BT and BB.

The embedded passage wiring LV1-LV4 and LH1-LH3 are formed on the same layer as the bit lines or upper. The embedded passage wiring LV1-LV4 and LH1-LH3 are metal preparation lines to be used for signal line routing. Two lines (LV1 and LV2; and LV3 and LV4) are arranged within each vertical path, formed between adjacent memory cells 10.

A terminal V1 is connected to one end of the embedded passage wiring LV1, and a terminal V6 is connected to the other end of the passage wiring LV1. A terminal V2 is connected to one end of the embedded passage wiring LV2, and a terminal V5 is connected to the other end of the passage wiring LV2. A terminal V3 is connected to one end of the embedded passage wiring LV3, and a terminal V8 is connected to the other end of the passage wiring LV3. A terminal V4 is connected to one end of the embedded passage wiring LV4, and a terminal V7 is connected to the other end of the passage wiring LV4. Terminals H1 and H4 are connected to the ends of the embedded passage wiring LH3; terminals H2 and H5 are connected to the ends of the embedded passage wiring LH2; and terminals H3 and H6 are connected to the ends of the embedded passage wiring LH1.

The embedded passage wiring LV1-LV4 and LH1-LH3 are electrically connected to signal lines (12, 14, 16 and 18) via the terminals to route the signal lines over the on-chip memory using a Place & Routing tool. In FIG. 4, signal lines 12 and 14 are connected to the embedded passage wiring LV1 and LV2 via the terminals V1 and V5, respectively. Signal lines 16 and 18 are connected to the embedded passage wiring LH2 via the terminals H2 and H5, respectively.

According to the third preferred embodiment, two lines (LV1 and LV2, LV3 and LV4) are arranged within each vertical path, formed between adjacent memory cells 10; and the embedded passage wiring LV1 and LV2 (LV3 and LV4) are arranged to cut across each other at a predetermined point at least in a plane view so as to decrease the length of signal lines that continuously extends parallel to the bit lines. As a result, the vertically extending lines LV1-LV4 can be arranged close to the bit lines.

What is claimed is:

1. An integrated circuit, comprising:
an on-chip memory having bit lines, which is formed in a metal layer; and
an embedded passage wiring that is arranged at a region so as to avoid a cross-talk noise with the bit lines,
wherein the embedded passage wiring is electrically connected to a signal line to route the signal line over the on-chip memory, and said embedded passage is arranged so as to extend in a direction not parallel to the bit lines.

2. An integrated circuit according to claim 1, wherein the embedded passage wiring comprises a first line extending perpendicular to the bit lines, and a second line extending in a direction slightly leaning from the bit lines.

3. An integrated circuit according to claim 1, wherein the integrated circuit comprises a plurality of the on-chip memories, which are located adjacent each other not to have any specific region therebetween for a signal line.

4. A method for fabricating an integrated circuit, comprising:
providing an on chip memory with bit lines on a semiconductor substrate;
forming an embedded passage wiring at a region so as to avoid a cross-talk noise with the bit lines;
electrically connecting the embedded passage wiring to predetermined terminals to route a signal line over the on-chip memory;
wherein the embedded passage is arranged so as to extend in a direction that is not parallel to the bit lines.

5. A method according to claim 4, wherein the embedded passage wiring comprises a first line extending perpendicular to the bit lines, and a second line extending in a direction slightly leaning from the bit lines.

6. A method according to claim 4, wherein the integrated circuit comprises a plurality of the on-chip memories, which are located adjacent each other not to have any specific region therebetween for a signal line.
